(19) United States
(12) Patent Application Publication
(10) Pub. No.: US 2008/0303432 A1
(43) Pub. Date: Dec. 11, 2008

(54) Systems and methods for improving the qualities of polymer light-emitting electrochemical cells

(76) Inventors: Yan G. Shao, Goleta, CA (US); Guillermo C. Bazan, Santa Barbara, CA (US); Alan J. Heeger, Santa Barbara, CA (US); Xiong Gong, Goleta, CA (US)

Correspondence Address: Richard Y. M. Tun;BERLINER & ASSOCIATES, 31st Floor, 555 W. Fifth Street, Los Angeles, CA, 90013, US

(21) Appl. No.: 12/152,526

(22) Filed: May 15, 2008

Related U.S. Application Data
(63) Continuation-in-part of application No. 11/655,324, filed on Jan. 18, 2007.
(60) Provisional application No. 60/850,227, filed on Oct. 5, 2006.
(60) Provisional application No. 60/931,304, filed on May 21, 2007.
(60) Provisional application No. 60/995,398, filed on Sep. 25, 2007.

(51) Int. Cl. H01L 51/52

(52) U.S. Cl. 313/504

(57) ABSTRACT

A light-emitting device comprising a pair of electrodes, and an emitting polymer active layer between the pair of electrodes, and either a) an electron transport layer, b) a hole transport layer, or c) a low work function material layer, wherein said emitting polymer layer comprising a single phase combination of a light-emitting polymer and an ionic liquid, is provided. Such multilayered devices have increased stability at relatively high voltages, fast turn-on times, low operating voltage, high brightness and long lifetimes.

### CROSS-REFERENCE TO RELATED APPLICATIONS

This application claims the benefit of Provisional Patent Application Nos. 60/931,304, filed May 21, 2007, and 60/995,398 filed Sep. 25, 2007, both of which are incorporated herein in their entirety. This application is also a continuation in part of U.S. application Ser. No. 11/655,324, filed on Jan. 18, 2007, which is incorporated herein in its entirety, which claims priority of U.S. Provisional application 60/850,227, filed on Oct. 5, 2006, which is also incorporated in its entirety.

### FIELD OF INVENTION

The field of the invention generally relates to systems and methods for polymer light emitting electrochemical cells.

### BACKGROUND

Light-emitting polymers (LEPs) and related emitting devices have been extensively investigated for more than one decade.^{1, 2, 3, 4, 5, 6, 7, 8, 9, 10, 11, 12, 13, 14, 15}. Polymer light-emitting diodes (PLEDs)^{1, 2, 3, 4, 5, 10, 11, 12, 13} and polymer light-emitting electrochemical cells (PLECs)^{6, 7, 8, 9, 14, 15} have drawn research attention in academia and industrial laboratories because of their potential applications in solid state lighting and in high information content displays. One of the most important characteristics for PLECs is that the built-in p-i-n junction can be formed by redistribution of the mobile ions. As a result, no low work function metal or interface is required for electron injection. However, the heavy doping (redox doping) effects near the electrodes can affect the stability of the devices, especially under relatively high operating voltages that are outside the electrochemical stability windows of the component materials. As a result, PLECs typically have relatively short device lifetimes, especially at high operating voltages. This lifetime issue has become the biggest obstacle for the applications of PLECs. In addition, the contact between light-emitting layer and conducting anode affects the stability of the devices. Moreover, the ion redistribution in PLECS is a relatively slow process compared with electron or hole transport in semiconducting polymers. Therefore, PLECs often show a continuous (and slow) increase in emission after the electric field is applied

Recently, long lifetime PLECs have been invented¹⁶; these PLECs exhibit a frozen junction at room temperature and show characteristics like those of PLEDs after the frozen junctions⁹ are formed: high current-rectification, short response time, and long lifetime without the help of low wok function metals or interfaces. The frozen junction is created by ion redistribution in the polymer layer under an applied electric field, which is a relatively slow process at room temperature because the very small diffusion coefficients for the ions inside polymer at room temperature. A solution to this is to operate this process under elevated temperature (e.g. 80° C.) to accelerate this process; at this relatively high temperature, the junction can be formed in minutes. The ion source used in the high performance PLECs is methyltrioctylammonium trifluoromethanesulfonate (MATS) and the semiconducting polymer for light-emission is the soluble phenyl-substituted poly(para-phenylene vinylene) (PPV) copolymer (“superyellow” from Merck/Covion)³. One of the important advantages of these new PLECs is the excellent compatibility of the materials^{17, 18} which ensures a thermodynamically stable light-emitting system with, as a consequence, a long device lifetime. Compared with the previous PLECs^{6, 7, 8, 9, 14, 15}, another advantage is that the material system for this new type of PLECs is a single-phase solid solution with only two components: a dilute concentration of ionic liquid in the light emitting polymer¹⁶. The use of this solid solution material simplifies the device fabrication processes and it would be easy to control the uniformity of the thin films. From another point of view, MATS can be used as tracer for internal electrical field in the polymer layer because it can be uniformly dissolved in superyellow, and it will move under the high electric field.

### BRIEF SUMMARY OF THE INVENTION

The present invention overcomes the foregoing drawbacks by providing a light-emitting device comprising a pair of electrodes, and an emitting polymer active layer between the pair of electrodes, and either a) an electron transport layer, b) a hole transport layer, or c) a low work function material layer, wherein said emitting polymer layer comprising a single phase combination of a light-emitting polymer and an ionic liquid.

In one construction, a light-emitting device is provided comprising of emitting polymer layer comprising a single phase combination of a light-emitting polymer and an ionic liquid where a hole transport layer is present between a light emitting layer and an anode. In a more particularized construction, the hole transport layer is comprised of a cross-linkable material that contains at least either of arylamine or carbazol in its structure.

In another embodiment, a light-emitting device is provided comprising of emitting polymer layer comprising a single phase combination of a light-emitting polymer and an ionic liquid where the low work function material layer has a material with an ionization potential is less than 2.0 eV. In yet another embodiment, the light-emitting device has a low work function material selected from elements within group 1 or 2 of the periodic table of the elements.

In another construction, a process for forming a light emitting device, comprising a pair of electrodes, and an emitting polymer active layer between the pair of electrodes, said emitting polymer layer comprising a single phase combination of a light-emitting polymer, and an ionic liquid, and a hole transport layer, is provided formed by the step of coating a p-doped layer with a layer of a crosslinkable material; crosslinking said material; depositing onto the layer of crosslinkable material, a layer of a solution comprising the host light-emitting polymer and the ionic liquid containing a concentration of mobile ions, and evaporating aluminum through a mask to form a cathode.

In one embodiment, a light-emitting device is provided comprising of emitting polymer layer comprising a single phase combination of a light-emitting polymer and an ionic liquid where the electron transport layer is between the cathode and the light emitting layer. In another embodiment, the electron transport layer is a titanium oxide having the formula of TiOx where x is from 1 to 2. In yet another embodiment, the aforementioned light emitting device includes a hole transport layer between the light emitting layer and the anode, in which the hole transport layer comprises a cross-linkable material.

Advantages of the foregoing devices are increased stability of the device at relatively high voltages; fast turn-on times, low operating voltage, high brightness and long lifetimes.

### BRIEF DESCRIPTION OF DRAWINGS

FIG. 1 (a) Chemical structures of PS-TPD and VB-TCTA and (b) Schematic device structure.

FIG. 2 Atomic force microscope image for (a) PS-TPD and (b) VB-TCTA layers on PEDOT-PSS.

FIG. 3 Current-voltage (I-V) curves showing the photovoltaic effects of the devices before (solid square) and after 80° C. heating under 5V forward bias (circle) for (a) device A and (b) device B.

FIG. 4 Current-voltage (I-V) and brightness-voltage (B-V) curves of (a) device A and (b) device B.

FIG. 5 Brightness vs time (continuous operation mode) for the device A, device B, and control device with structure ITO/PEDOT-PSS/2 wt % MATS in superyellow/Al.

FIG. 6 The current-voltage (I-V) characteristics for the device ITO/PEDOT/2% MATS in superyellow/Ba/Al before and after charging.

FIG. 7 The current-voltage-brightness (I-V-B) characteristics for the device ITO/PEDOT/2% MATS in superyellow/Ba/Al under continuous operation with constant current.

FIG. 8 (a) Comparison for the decay curves of regular PLED with pure superyellow and the device with 2% MATS in superyellow. (b) Comparison for the operational voltage curves of regular PLED with pure superyellow and the device with 2% MATS in superyellow.

FIG. 9 shows (a) schematic diagram of the multilayered polymer LEC, (b) Molecular structure of the crosslinked hole transport material (crosslinked VB-TCTA), and (c) a schematic diagram of the TiOₓ amorphous network;

FIG. 10 shows plots of current-voltage (I-V) and brightness-voltage (B-V) curves obtained from the multilayered polymer LEC;

FIG. 11 shows plots of current-voltage (I-V) curves showing the photovoltaic effects of the devices before heating (solid square) and after 80° C. heating under 4V forward bias (open circle); and

FIG. 12 a plot of a stress test of the multilayered polymer LEC under constant current (continuous operation).

### DETAILED DESCRIPTION

In order to realize the multilayered structure PLECs of the present invention, appropriate charge transport materials must be utilized. The requirements for charge transport materials in polymer LECs are very different from those for polymer LEDs because there are no strict requirements for energy level alignment in polymer LECs. The basic requirements for selecting charge transport materials for use in polymer LECs are high carrier mobility and good stability. In order to obtain long lifetime and maintain the potential for low cost manufacturing, stable materials that can be processed from solution are preferred. Organic hole transport materials have been developed into a large family^{19, 20}; many show high performance and good stability in polymer LEDs, including crosslinkable hole transport materials^{21, 22, 23, 24}. The stability of the crosslinked hole injection layer enables the casting of subsequent layers from solution without destroying the hole transport film.

Most of the electron transport materials used in polymer LEDs are not very stable or not suitable for solution processing²⁰. Additionally, most traditional polymer LECs use multi-phase material systems for light-emitting layer. As a result, it is difficult to select a suitable solvent for the electron transport layer that can be cast from solution without destroying the light-emitting layer. In accordance with the invention, this problem can be overcome by adopting the recently developed single-phase light emitting system for polymer LECs¹⁶ in combination with either a crosslinked hole transport layer, a low work function material layer or a combination of both hole and electron transport layers.

### A. PLECs with a Single-Phase Light Emitting System

A soluble mixture is provided comprised of a single phase combination of a light-emitting polymer and a soluble ionic liquid.

The light emitting polymer of the present invention is a compound selected from the group consisting of phenyl-substituted poly(para-phenylene vinylene) (PPV) copolymer, and its derivatives substituted at various positions on the phenylene moiety, poly(2-methoxy-5-(2-ethylhexyloxy)-1,4-phenylene-vinylene) (MEH-PPV), polyfluorenylene (PF), poly(1,4-phenylene) (PP), and other derivatives. In general, the derivatives can have alkyl, alkoxyl, phenyl, and phenoxyl groups.

The ionic liquid of the present invention is a compound selected from the group of toluene soluble ionic liquids consisting of methyltrioctylammonium trifluoromethanesulfonate (MATS), 1-Methyl-3-octylimidazolium octylsulfate, 1-Butyl-2,3-dimethylimidazolium octylsulfate, 1-octadecyl-3-methylimidazolium bis(trifluoromethylsulfonyl)imide, 1-octadecyl-3-methylimidazolium tris(pentafluoroethyl)trifluorophosphate, 1,1-dipropylpyrrolidinium bis(trifluoromethylsulfonyl)imide, trihexyl(tetradecyl)phosphonium bis(1,2-benzenediolato(2-)-O,O′)borate, and N,N,N′,N′,N″-pentamethyl-N″propylguanidinium trifluoromethanesulfonate.

The merits of MATS include its good solubility in common organic solvents, such as toluene, hexane, and acetonitrile, and its relatively high decomposition temperature (approximately 220° C.). Because MATS has a melting temperature of approximately 56° C., frozen junction devices can be prepared for operation at room temperature.

Other solvents can include 1,1-dichloroethane, 1,2-dichloroethane, dichloromethane, benzene, dialkylbenzene, dialkoxylbenzene, chloroform, hexane, cyclohexane, and cyclohexanone.

In a particular embodiment, a soluble phenyl-substituted poly(para-phenylene vinylene) (PPV) copolymer (“superyellow”) was used as the host light-emitting polymer and methyltrioctylammonium trifluoromethanesulfonate, an ionic liquid, was used to introduce a dilute concentration of mobile ions into the emitting polymer layer.

### B. The Addition of a Crosslinkable Hole Transport Layer to PLECs

A PLEC is provided that possess an emitting polymer layer comprising a single phase combination of a light-emitting polymer and an ionic liquid and a crosslinkable hole transport layer. The crosslinkable hole transport material can be inserted between an anode and the active polymer layer. The device stability is improved because there is no direct contact between anode and doped polymer.

### EXAMPLE 1

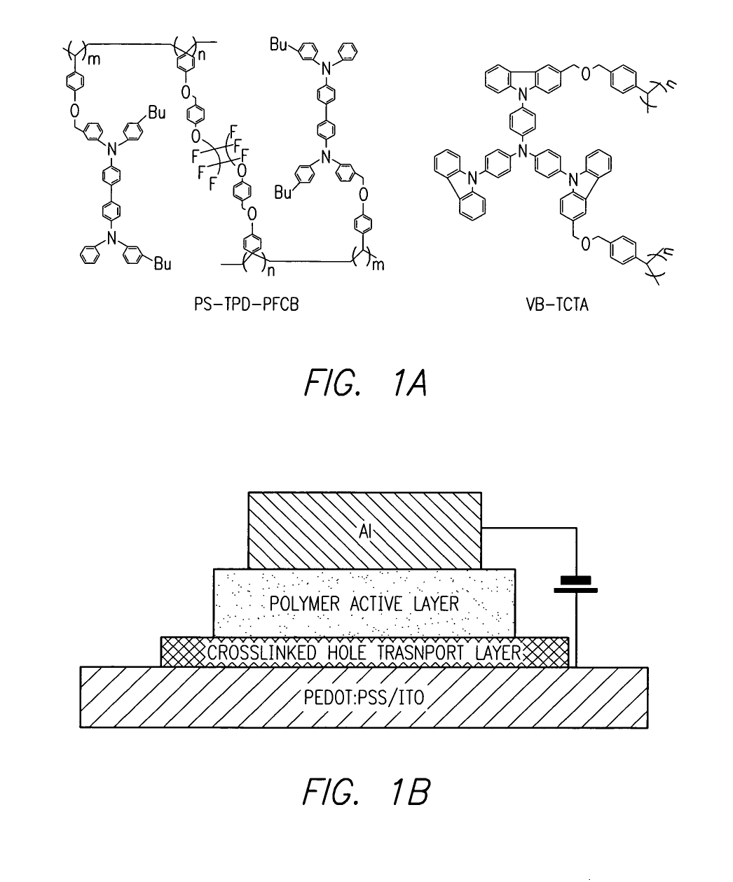

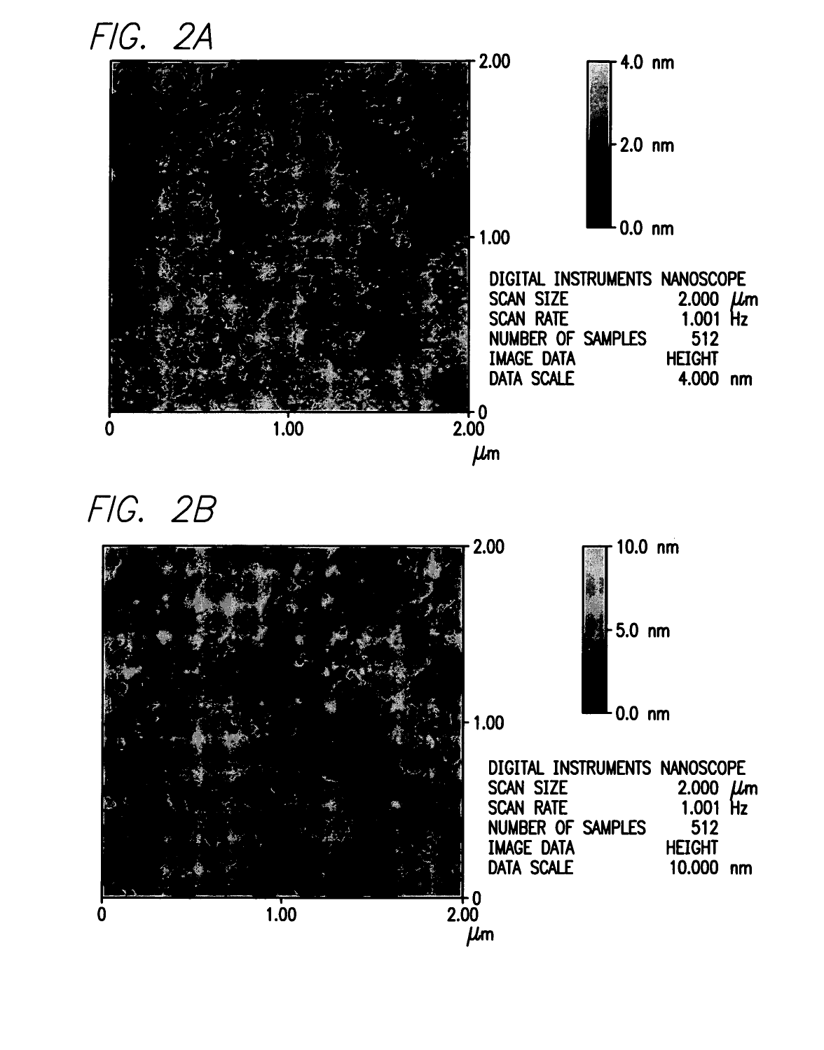

Two crosslinkable materials that can be used in the crosslinkable hole transport layer are, but not limited to, polystyrene(PS)-N,N′-diphenyl-N,N′-bis(4-n-butylphenyl)-(1,1′-biphenyl)-4,4′-diamine(TPD)-perfluorocyclobutane(PFCB) (PS-TPD-PFCB) and 4,4′,4″-tris(N-carbazoly) triphenylamine bis(vinylbenzylether) (VB-TCTA)^{26, 27, 28, 29}. FIG. 1 shows their molecular structures and a schematic diagram of the device structures. The synthesis and characteristics of PS-TPD-PFCB and VB-TCTA were reported elsewhere^{26, 27, 30}. The advantages of using these two materials include solution-processible ability, simple thermal crosslinking with no side products involved. Both PS-TPD-PFCB and VB-TCTA were dissolved in 1,2-dichloroethane and the 0.5 weight percent solutions were utilized to form thin films on PEDOT-PSS anode by coating with a spin speed of 3000 rpm. Two-step heating process for crosslinking were conducted in nitrogen glove box: 100° C. heating for 40 minutes and then 200° C. heating for 1 hour. The thickness was determined by atomic force microscope (AFM) as 12 nm for PS-TPD-PFCB layer and 6 nm for VB-TCTA layer, respectively. (FIG. 2(a)) The room-mean-square (RMS) roughness of the two thin films is about 0.5 nm and 1.6 nm, respectively. (FIG. 2(b))

After heating, the thin films were cooled to room temperature and 6 mg/ml soluble phenyl-substituted poly(para-phenylene vinylene) (PPV) copolymer (“superyellow” from Merck/Covion) ³ with two weight percent methyltrioctylammonium trifluoromethanesulfonate (MATS) as ion source in toluene was coated onto the crosslinked thin films with a spin speed of 1500 rpm. After annealing film at of 80° C. for 30 minutes, 120 nm Al was thermally deposited as the cathode under a vacuum of about 10⁻⁶ torr (1 torr=133 Pa) through shadow masks. The active device area was 14.8 mm². The thickness of superyellow layer was about 50 nm which was determined by AFM. The device with a structure of ITO/PEDOT/PS-TPD-PFCB/superyellow:2% MATS/Al is labeled as device A and the device ITO/PEDOT/VB-TCTA/superyellow:2% MATS/Al is labeled device B in the following paragraphs.

Initially, without prebias and heating, the devices showed poor performance; before the ion redistribution, the electron injection form Al was difficult. After heating at 80° C. under 5V forward bias for about 1.5 minutes, the current increased approximately 1000 times. Then, the devices were cooled to room temperature to freeze in the junction. In this process, the anions moved toward the ITO anode and cations moved toward the Al cathode. As a result, the effects of the cation double layer made the electron injection much easier than before (ionic current only represented a very small part in the current since ion source was very limited). On the other hand, the anions were blocked from the vicinity of the anode by the crosslinked hole transport layers. The frozen p-i-n junction was stable at room temperature for several hours without external electrical field since MATS has a melting point of 56° C. and superyellow possesses a T_{g} of around 80° C.

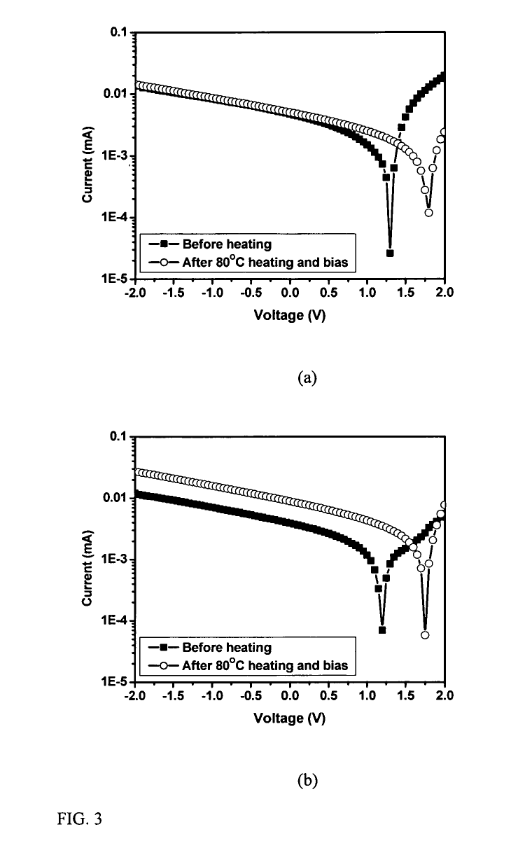

The existence of the p-i-n junction was confirmed by measuring the built-in potentials of the devices. Photovoltaic effect measurements under AM 1.5 solar illumination at 100 mW/cm² (1 sun) were performed in nitrogen glove box to obtain the open circuit voltages (V_{OC}) as a measure of the built-in potentials. The built-in potentials for the two devices changed significantly after the ion redistribution. FIG. 3 shows the changes of the built-in potentials for the two PLECs. After ion redistribution, the V_{OC} of device A changed from 1.30 V to 1.75 V (FIG. 3(a)) and the V_{OC} of device B changed from 1.15 V to 1.75 V (FIG. 3(b)).

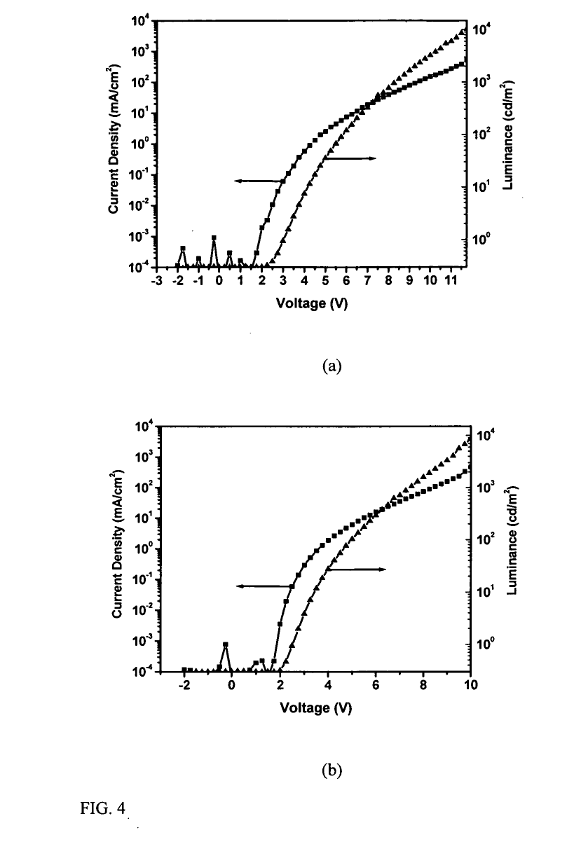

FIGS. 4(a) and (b) shows the voltage-current density-brightness curves for device A and device B, respectively. In device A, the turn-on voltage is approximately 3.0V (1 cd/m²) and the maximum brightness is about 10,000 cd/m² at 11.5V. The current efficiency of the device changes from 1.5 cd/A at 4V to 2.5 cd/A at 11V. In device B, the turn-on voltage is approximately 2.5 V (1 cd/m²) and the maximum brightness is about 9000 cd/m² at 9.0 V. The current efficiency again changes from 1.5 cd/A at 4 V to 2.5 cd/A at 9.5 V. In both cases, the current efficiencies increase when the current densities increase, a result which was not seen previously from traditional PLECs. The control PLECs without the crosslinked hole transport layers were fabricated and measured. The maximum current efficiency occurred at low operating voltages and device efficiency decreased slowly when the voltage and current density increased. With the help of the crosslinked layers, the carrier currents are more nearly balanced at relatively high operating voltages. Another function for crosslinked hole transport layers might be the electron blocking effect, which helps to improve device efficiencies at relatively high voltage when the electron injection is very strong.

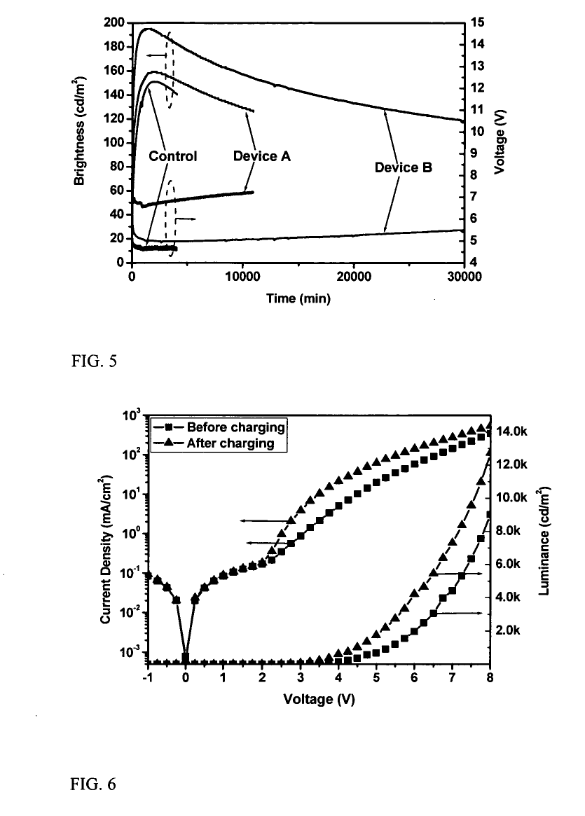

More importantly, the crosslinkable hole transport layers further enhanced the device lifetime of these new PLECs. FIG. 5 shows the device decay trends for devices A and B, and the control device without the crosslinked layer. All the devices were measured from the original status without prior heating. The data clearly illustrate that the lifetimes are enhanced by the crosslinked hole transport layer. In FIG. 2 shows that the surfaces of the crosslinked hole transport layers were not very smooth. Therefore, the morphology did not contribute to the enhanced lifetimes and the lifetimes were not very dependent on the roughness of the surface, which is a little different from earlier observations on PLEDs

Thus, two kinds of crosslinkable hole transport materials have been introduced into the ionic liquid containing PLECs to enhance the performance. By separating the light-emitting layer from conducting PEDOT-PSS layer, the device stability at high voltages has been improved and better lifetimes have been obtained.

### C. The Addition of Low Work Function Material Layer to PLECs

A PLEC device is provided that possess an emitting polymer layer comprising a single phase combination of a light-emitting polymer and an ionic liquid and a low work function material layer for electron injection. Such low work function material would preferably have an ionization potential of less than 2.0 eV and be an element selected from Group 1 or 2 of the periodic table of elements. Preferred elements within these groups are barium, calcium, and alloys comprising barium and calcium.

### EXAMPLE 2

In this example, barium (Ba) was used as the low work function electron injecting interface material, in addition to using Al as protection cathode, and MATS as mobile ion source inside the semiconducting polymer. Polymer light-emitting devices were fabricated by spin-casting 6 mg/ml superyellow with two weight percent MATS inside from solution in toluene onto poly(3,4-ethylenedioxythiophene)-poly(styrene sulfonate) (PEDOT-PSS) coated indium-tin-oxide (ITO) glass (spin speed of 1500 rpm). After deposition of the polymer film, 5 nm Ba and 100 nm Al were deposited in a vacuum of about 10⁻⁶ torr. All the device fabrication processes were performed in nitrogen glove box with oxygen level of about 3 ppm. The thickness of PEDOT-PSS and active polymer layers were determined by atomic force microscopy (AFM) as 40 nm and 50 nm, respectively. For comparison, PLEDs without MATS were also fabricated under similar process conditions.

All electrical measurements were performed under nitrogen in the glove box. The current-voltage (I-V) characteristics were recorded by a computer controlled Keithley 236 source-measure unit (SMU).

The as-fabricated device showed typical PLED behavior with a turn-on voltage of about 2.33 V (@1 cd/m²), which was very close to the band gap of the semiconducting polymer. After several forward scans from 0 to 8 V, the device was “charged” by the external electrical field at room temperature. In processing, the mobile ions will move under the internal electrical field: anions to anode and cations to cathode. In ideal case, the ions would pile up near the two surfaces of the polymer active layer and the center part of the layer would have almost no electrical field. As a result, the charge injections were enforced after this processing. FIG. 6 shows the device I-V curves before and after charging. After charging, the turn-on voltage was 2.18 V (@1 cd/m²), slightly lower than before charging. The consequent enhancement of device brightness also confirmed the effect of the ion redistribution. As can be seen from FIG. 6, before charging the brightness at 4 V was only about 150 cd/m², whereas after charging the brightness at 4 V increased to nearly 600 cd/m². The injected currents also increased by a factor of 4 after charging. The device emission efficiencies, therefore, remained at approximately 3 cd/A. There was no evidence of this kind of charging effect in regular PLEDs with pure superyellow as the active semiconductor polymer.

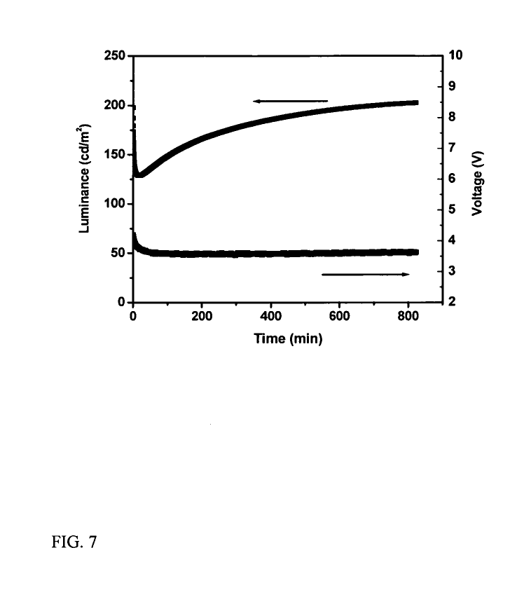

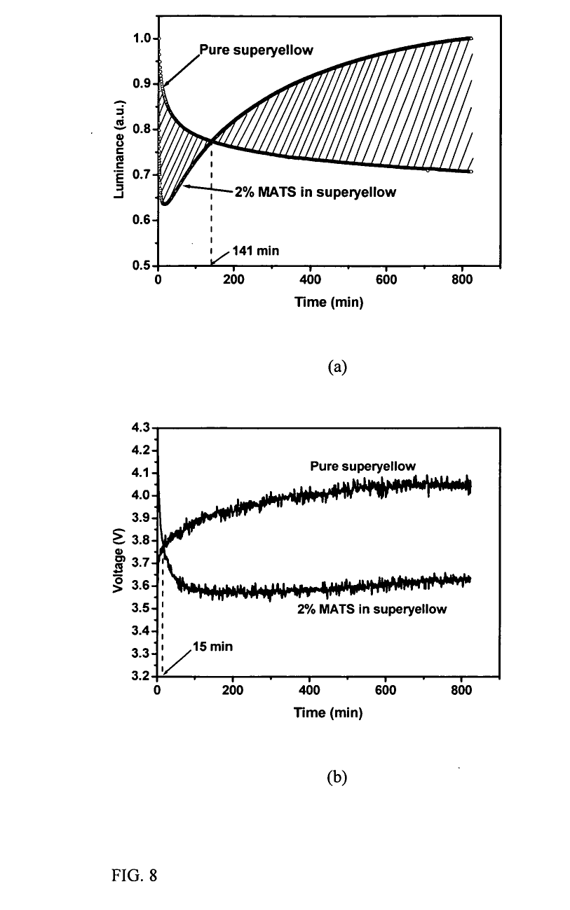

As shown in FIG. 7, an interesting hybrid transition behavior from PLEDs to PLECs was found during continuous operation. The device was operated in constant current mode at 6.76 mA/cm² without prior charging. The operating voltage was highest at the beginning of the experiment. The voltage was always below 4 V after 4 minutes continuous operation, and it was lower than that of the control PLED with the same constant current after approximate 15 minutes operation (FIG. 8(b)). The brightness initially decreased from 200 cd/m² to 128 cd/m² during approximately 20 minutes. During the same period, the operating voltage dropped from 4.2 V to 3.7 V.

There were two effects responsible for this initial decay in brightness, which are related to the characteristics of PLEDs and PLECs, respectively. The initial rapid turn-on is characteristic of PLED behavior. However, degradation of the reactive low work function cathode resulted in the rapid initial decay in brightness. After a short time, however, the ions started to move under the applied electric field and the redox doping characteristic of LECs was initiated. As a result of the redox doping, charge injection of both electrons and holes was enhanced.

After approximately 20 minutes continuous operation, the degradation decay of the PLED and the enhancement of the PLEC reached a balance point, and the brightness started to increase. The brightness was fully recovered after 620 minutes continuous operation and continued to increase very slightly, reaching the highest point after another two hundred minutes operation. The overall lifetime of the device had been enhanced by the PLEC effect. Further independent measurement shows there was only approximate 10% brightness decay after another 10,000 minutes operation (measured from the point of highest brightness); a time of order 1000 times longer than that of the control PLED (for the same 10% decay).

FIG. 8 shows the trends of the brightness decay and operational voltages for the control PLED with pure superyellow and the device with 2% MATS in superyellow. The brightness of device with 2% MATS in superyellow is beyond that of the control PLED after 141 minutes operation and the corresponding operating voltage is less than that of the control after approximately 15 minutes. In FIG. 8(a), the shadow area before 141 minutes shows the loss of the luminance and the shadow area after 141 minutes shows the gain of the luminance both because of ion redistribution and electrochemical redox doping. As shown in FIG. 8(b), the operating voltage for the device with 2% MATS in superyellow is lower than that of the control PLED after 15 minutes continuous operation and the voltage difference between them is kept as approximately 0.4V, which also reflects the benefit of the PLEC mechanism.

This LED to LEC transition behavior reflects the characteristics of ion redistributions and consequent built-in p-i-n junction in PLECs and the strong internal electrical field inside the active polymer of PLEDs. The combination with LEC effect with LED enhanced the light-emitting performance by further lowering operational voltage and improving the device lifetime.

Thus, hybrid polymer light-emitting devices with the combined features of PLEDs and PLECs were fabricated and investigated. An interesting transition behavior from PLED to PLEC was observed under continuous operation. This transition behavior results directly from the hybrid nature of the device operation, which could be utilized to analyze the internal electrical field of the devices and enhance device performance. Hybrid polymer light-emitting devices exhibit fast turn-on with low turn-on voltage, low operating voltage, and relatively long lifetime with brightness and efficiency comparable to PLEDs.

### D. Multilayered PLEC Devices with Electron Transport and Hole Transport Layers

In accordance with another embodiment of this invention, a PLEC device is provided that possess an emitting polymer layer comprising a single phase combination of a light-emitting polymer and electron transport and hole transport layers.

### EXAMPLE 3

The above embodiment can be formed by the process of i) depositing onto the anode of a layer of a solution comprising the host light-emitting polymer and the ionic liquid containing a concentration of mobile ions, ii) spin-coating on the light-emitting polymer layer of a precursor solution of TiOx followed by 50-150° C. baking; and iii) evaporating aluminum through a mask to form a cathode.

In specific embodiments, the device is prepared by i) coating a p-doped layer with a layer of a crosslinkable material, ii) cross-linking said material, iii) depositing onto the layer of crosslinkable material, a layer of a solution comprising the host light-emitting polymer and the ionic liquid containing a concentration of mobile ions, iv) spin-coating on the light-emitting polymer layer of a precursor solution of TiOx followed by 50-150° C. baking; and v) evaporating aluminum through a mask to form a cathode.

The TiOₓ layer is formed by sol-gel chemistry starting with a soluble precursor material and has excellent stability after forming the sub-oxide by hydrolysis. The lowest unoccupied molecular orbital (LUMO) and highest occupied molecular orbital (HOMO) energy levels are 4.4 and 8.1 eV³¹. The LUMO level is close to the work function of Al (˜4.2 eV) but significantly lower in energy than that of the LUMO of superyellow. This mismatch makes TiOₓ a poor electron injection material in polymer LEDs. In LECs, however, electron injection form TiOₓ will not be a problem because of the redox doping of the polymer. Moreover, electron injection from Al to the TiOₓ layer will be facile because of the good match between the TiOₓ LUMO and the AI Fermi level.

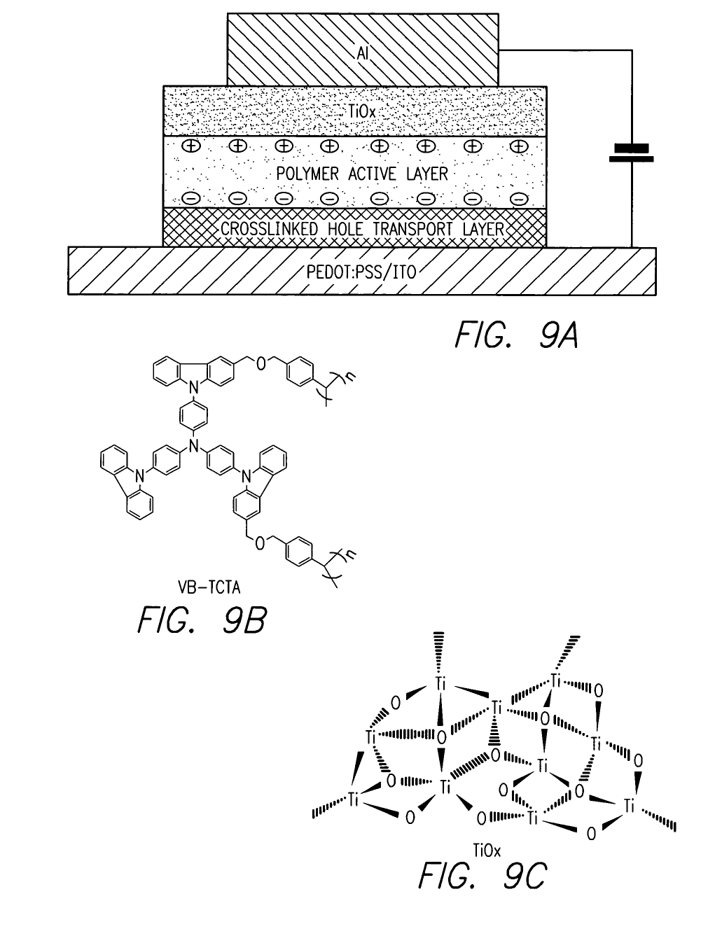

Presented are results obtained from multilayer polymer LECs using crosslinked 4,4′,4″ -tris(N-carbazoly) triphenylamine bis(vinylbenzylether) (VB-TCTA)(22) (see FIG. 9b) as the hole transport material and TiOₓ as the electron transport material(see FIG. 9c). Nevertheless, polystyrene(PS)-N,N′-diphenyl-N,N′-bis(4-n-butylphenyl)-(1,1′-biphenyl)-4,4′-diamine(TPD)-perfluorocyclobutane(PFCB) (PS-TPD-PFCB) could have been used as the crosslinkable hole transport material.

VB-TCTA can be cast into thin films from solution and subsequently stabilized by thermally induced crosslinking. The light-emitting layer can then be cast from solution in an organic solvent onto the crosslinked VB-TCTA. For the single-phase light-emitting material system, we have used soluble phenyl-substituted poly(para-phenylene vinylene) (PPV) copolymer (“superyellow” from Merck/Covion)³ with two weight percent ionic liquid, methyltrioctylammonium trifluoromethanesulfonate (MATS), as the ion source¹⁶. In order to avoid dissolving the light-emitting layer, toluene was used for processing the light-emitting layer and methanol was used for processing the TiOₓ electron transport layer. The amorphous TiOₓ film was formed by heating to −80° C. FIG. 9a shows a schematic diagram of the device structure. Al was deposited in high vacuum as the cathode. The thickness for hole transport layer, emitting layer, and electron transport layer are 6 nm, 50 nm, and 5-10 nm, respectively.

The frozen p-i-n junction can be formed by heating the fully assembled device to approximately 80° C. for about 1 minute under 5 V forward bias, followed by cooling to room temperature under the same 5V bias. During this process, both redox doping (n-type on the cathode side and p-type on the anode side) and ion redistribution take place. When heated, the current density increased rapidly from tens μA/cm² to over 10 mA/cm² as a result of in-situ doping and the formation of the p-i-n junction; electrochemical doping lowers the device resistance. The frozen junction must be located inside the polymer layer because only the polymer is capable of redox doping and because the ions are confined within the light-emitting layer by crosslinked networks of charge transport layers.

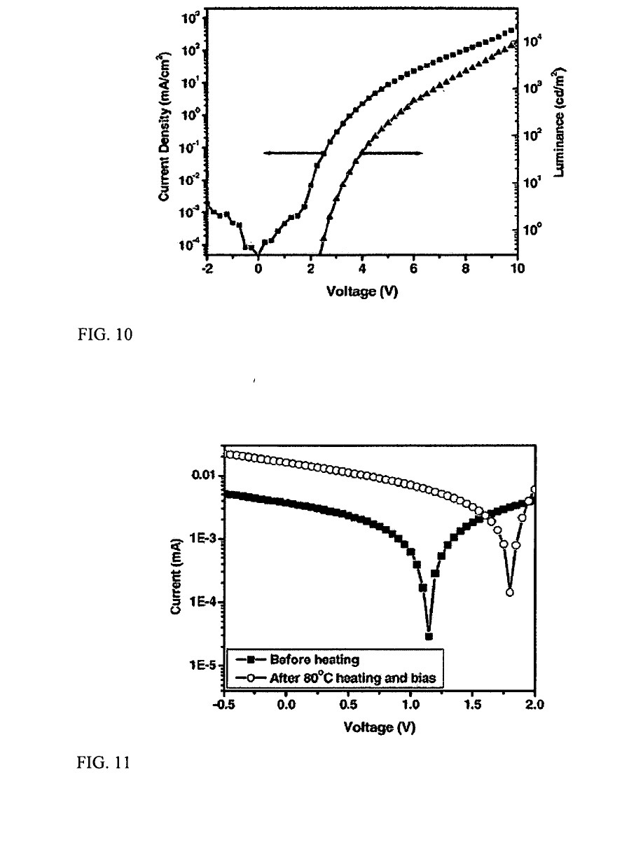

FIG. 10 shows the device performance at room temperature, after the frozen junction was formed. The device turns-on voltage at 2.5 V with a brightness of 1 cd/m², approximately 0.3 V higher than the single layer device (16). The device turn-on voltage is still close to the energy gap of superyellow, which is about 2.4 eV. Any series resistance from either the hole transport layer or the electron transport layer is relatively small. As shown in FIG. 10, the brightness reaches 10,000 cd/m² at about 10 V with an efficiency close to 3 cd/A.

The formation of the frozen p-i-n junction was confirmed by measurement of the photovoltaic open circuit voltage (Voc); the increase in Voc is a direct measure of the built-in potential. As shown in FIG. 11, the built-in potential of 1.15 V before the formation of the p-i-n junction increased to 1.80 V after formation of the junction.

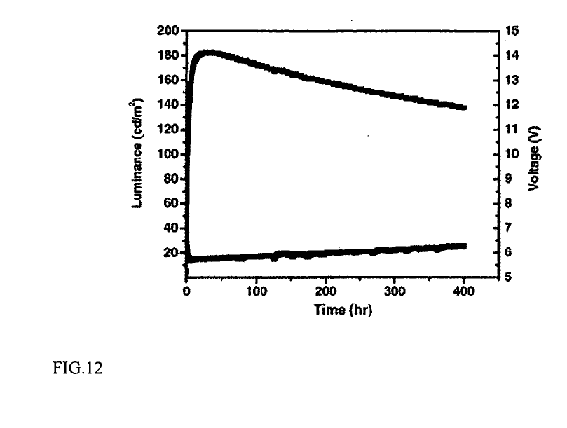

Device lifetime is a critical performance parameter. In earlier experiments, the polymer LEC device lifetime was enhanced by adopting the single-phase light emitting layer¹⁶. Here, the multilayer polymer LECs show even better lifetimes without further blending. FIG. 12 shows the data obtained from a long-time stress test of the multilayered polymer LEC. The device was tested in a nitrogen glove box with an oxygen level of about 3 ppm (without pre-heating and without encapsulation). The slow increase of the brightness at the beginning reflects the slow formation of the p-i-n junction. After about 400 hours (nearly 16 days) of continuous operation at constant current, the device brightness decayed by less than 25% relative to the maximum. brightness. During this time, the operating voltage increased by only about 0.5 V. The brightness decay curve can be fitted to an exponential one, which predicts a lifetime to approximately half brightness (100 cd/m²) after approximately 1500 hours (60 days). This relatively long lifetime suggests that multilayered polymer LECs can be optimized for use in commercial applications.

In summary, multilayered polymer LECs have been demonstrated with enhanced stability during operation. The multilayered polymer LECs with frozen p-i-n junction at room temperature have low turn-on voltage, relatively high efficiency, and high brightness.

### Materials Preparation

The solution-based titanium oxide was prepared from a sol-gel precursor in methanol. Ten ml (10 ml) of titanium (IV) isopropoxide (Ti[OCH(CH₃)₂]₄), 50 ml of 2methoxyethanol (CH₃OCH₂CH₂OH), and 5 ml of ethanolamine (H₂NCH₂CH₂OH) were mixed together in a three-necked flask under inert gas environment. The mixed solution was heated to 80° C. for 2 hours under stirring and then heated to 120° C. for one more hour. The excess solvent was evaporated, after which this sol-gel precursor was diluted into 1:200 by methanol.

Device Fabrication

Polymer LECs were fabricated on patterned ITO-coated glass substrates, which had been cleaned by successive ultrasonic treatment in detergent, acetone, and isopropyl alcohol. The ITO glass was then subjected to UV-ozone treatment for about 30 minutes. A thin layer of PEDOT-PSS film (˜40 nm) was spin-cast onto the ITO glass substrate with a spin speed of 4000 rpm for 1 minute and then baked at 120° C. for 20 minutes in ambient. The 0.5 wt % VB-TCTA in 1,2-dichloroethane solution was then spin-cast on top of PEDOTPSS layer, followed by baking at 200° C. for about 1 hour in a nitrogen glove box. The solution containing 1:50 weight ratio of MATS and superyellow in toluene was spin-cast in the nitrogen glove box (for 1 minute with spin-speed of 1500 rpm). The thickness of the superyellow layer was about 50 nm. The sol-gel precursor of solution-based titanium in methanol was spin-cast with a spin-speed of 6000 rpm outside the glove box, followed by 80° C. baking in ambient air for 10 minutes. The Al cathode was evaporated through a shadow mask with an active area of approximately 14.8 mm (vapor deposition of the aluminum cathode was carried out under a base pressure of ˜1×10⁻⁶ Torr with deposition rates about 4 Å/s.

Device Characterization

All electrical measurements were performed under nitrogen in the glove box. The current-voltage (I-V) characteristics and lifetime were recorded by a computer controlled Keithley 236 source-measure unit (SMU). The photocurrent was measured under AM 1.5 solar illumination at 100 mW/cm² (1 sun) in nitrogen glove box.

### REFERENCES

1. J. H. Burroughes, D. D. C. Bradley, A. R. Brown, R. N. Marks, K. Mackay, R. H. Friend, P. L. Burns, A. B. Holmes, Nature 1990, 347, 539.
2. D. Braun, A. J. Heeger, Appl. Phys. Lett. 1991, 58, 1982.
3. H. Spreitzer, H. Becker, E. Kluge, W. Kreuter, H. Schenk, R. Schmidt and H. Schoo, Adv. Mater, 1998 10, 1340.
4. X. Yang, D.C. Müller, D. Neher, K. Meerholz, Adv. Mater. 2006, 18, 948.
5. X. Gong, S. Wang, D. Moses, G. C. Bazan, A. J. Heeger, Adv. Mater. 2005, 17, 2053.
6. Q. B. Pei, G. Yu, C. Zhang, Y. Yang, A. J. Heeger, Science 1995, 269, 1086.
7. Q. B. Pei, Y. Yang, G. Yu, C. Zhang, A. J. Heeger, J. Am. Chem. Soc. 1996, 118, 3922.
8. J-H Shin, S. Xiao, L. Edman, Adv. Funct. Mater. 2006, 16, 949.
9. J. Gao, G. Yu, A. J. Heeger, Appl. Phys. Lett. 1997, 71, 1293.
10. Y. Cao, I. D. Parker, G. Yu, C. Zhang, A. J. Heeger, Nature, 1999, 397, 414.
11. Y. Xia, R. H. Friend, Adv. Mater. 2006, 18, 1371.
12. E. Aharon, A. Albo, M. Kalina, G. L. Frey, Adv. Funct. Mater. 2006, 16, 980.
13. J. Liu, Q. G. Zhou, Y. X. Cheng, Y. H. Geng, L. X. Wang, D. G. Ma, X. B. Jing, F. S. Wang, Adv. Funct. Mater. 2006, 16, 957.
14. G. Yu, Y. Cao, M. Andersson, J. Gao, A. J. Heeger, Adv. Mater. 1998, 10, 385.
15. J. M. Leger, D. B. Rodovsky, G. P. Bartholomew, Adv. Mater. 2006, 18, 3130.
16. Y. Shao, G. C. Bazan, A. J. Heeger, Adv. Mater. 2007, 19, 365.
17. Y. Shao, Y. Yang, Adv. Funct. Mater. 2005, 15, 1781.
18. Y. Shao, Y. Yang, Appl. Phys. Lett. 2005, 86, 073510.
19. U. Mitschke, P. Bauerle, 1. Mater. Chem. 10, 1471 (2000).
20. L. S. Hung, C. H. Chen, Mater. Sci. & Eng. R 39, 143 (2002).
21. Y-H Niu, M. S. Liu, J-W Ka, and A K.-Y. Jen, Appl. Phys. Lett. 88, 093505 (2006).
22. Y-H Niu, M. S. Liu, J-W Ka, J. Bardeker, M. T. Zin, R. Schofield, Y. Chi, and A. K.-Y. Jen, Adv. Mater. 19, 300 (2007).
23. J. Zhao, J. A. Bardecker, A. M. Munro, M. S. Liu, Y. Niu, I-K Ding, J. Luo, B. Chen, A. K.-Y. Jen, D. S. Ginger, Nano. Lett. 6, 463 (2006).
24. Y. Takahashi, Y. Matsuoka, J. Mater. Sci. 23, 2259 (1988).
25. Y-H Niu, M. S. Liu, J-W Ka, and A. K.-Y. Jen, Appl. Phys. Lett. 2006, 88, 093505.
26. S. Liu, X. Jiang, H. Ma, M. S. Liu, A. K.-Y. Jen, Macromolecules, 2000, 33, 3514.
27. J. Zhao, J. A. Bardecker, A. M. Munro, M. S. Liu, Y. Niu, I-K Ding, J. Luo, B. Chen, A. K.-Y. Jen, D. S. Ginger, Nano. Lett. 2006, 6, 463.
28. X. Jiang, S. Liu, M. S. Liu, P. Herguth, A. K.-Y. Jen, H. Fong, M. Sarikaya, Adv. Funct. Mater. 2002, 12, 745.
29. X. Gong, D. Moses, A. J. Heeger, S. Liu, A. K.-Y. Jen, Appl. Phys. Lett. 2003, 83, 183.
30. Y-H Niu, M. S. Liu, J-W Ka, J. Bardeker, M. T. Zin, R. Schofield, Y. Chi, and A. K.-Y. Jen, Adv. Mater. 2007, 19, 300.
31. A. Hayakawa, O. Yoshikawa, T. Fujieda, K. Uehara, S. Yoshikawa, Appl. Phys. Leu. 90, 163517 (2007).

1. A light-emitting device comprising a pair of electrodes, and an emitting polymer active layer between the pair of electrodes, and either a) an electron transport layer, b) a hole transport layer, or c) a low work function material layer, wherein said emitting polymer layer comprising a single phase combination of a light-emitting polymer and an ionic liquid.

2. The light-emitting device of claim 1b, wherein said hole transport layer is a layer between a light emitting layer and an anode.

3. The light-emitting device of claim 2, wherein said hole transport layer comprising a cross-linkable material, wherein said layer is between a light emitting layer and an anode.

4. The light-emitting device of claim 3, wherein the cross-linkable material contains at least either of arylamine or carbazol in its structure.

5. The light-emitting device of claim 4, wherein the cross-linkable material is polystyrene(PS)-N,N′-diphenyl-N,N′-bis(4-n-butylphenyl)-(1,1′-biphenyl)-4,4′-diamine(TPD)-perfluorocyclobutane(PFCB) (PS-TPD-PFCB) or 4,4′,4″-tris(N-carbazoly) triphenylamine bis(vinylbenzylether) (VB-TCTA).

6. The light-emitting device of claim 1c, wherein said low work function material layer has a material for electron injection with an ionization potential is less than 2.0 eV.

7. The light-emitting device of claim 6, wherein such material contains elements of group 1 or 2 on the periodic table of the elements.

8. The light-emitting device of claim 7, wherein such material is barium.

9. A light-emitting device comprising a pair of electrodes, and an emitting polymer active layer between the pair of electrodes, said emitting polymer layer comprising a single phase combination of a light-emitting polymer, and an ionic liquid, and a hole transport layer, said device formed by the process of:
i) coating a p-doped layer with a layer of a crosslinkable material;
ii) cross-linking said material;
iii) depositing onto the layer of crosslinkable material, a layer of a solution comprising the host light-emitting polymer and the ionic liquid containing a concentration of mobile ions, and
iv) evaporating aluminum through a mask to form a cathode.

10. A light-emitting device comprising a pair of electrodes, and an emitting polymer active layer between the pair of electrodes, said emitting polymer layer comprising a single phase combination of a light-emitting polymer and an ionic liquid, and a low work function material, said device formed by the process of:
i) coating a p-doped layer with a layer of a layer of a solution comprising the host light-emitting polymer and the ionic liquid containing a concentration of mobile ions, and
ii) depositing a layer of a low work function material and a layer of aluminum.

11. The light-emitting device of claim 1a, wherein the electron transport layer is between the cathode and the light emitting layer.

12. The light-emitting device of claim 1a in which the electron transport layer is a titanium oxide having the formula of TiOx where x is from 1 to 2.

13. The light-emitting device of claim la in which the electron transport layer having the thickness of 5-100 nm.

14. The light-emitting device of claim 12 in which the titanium oxide has the lowest unoccupied molecular orbital (LUMO) and highest occupied molecular orbital (HOMO) of 4.4 eV and 8.1 eV respectively.

15. The light-emitting device of claim 11, further including a hole transport layer between the light emitting layer and the anode.

16. The light-emitting device of claim 15 in which the hole transport layer comprises a cross-linkable material.

17. The light-emitting device of claim 16, wherein the cross-linkable material contains at least either of arylamine or carbazol in its structure.

18. The light-emitting device of claim 16, wherein the cross-linkable material is 4,4′,4″-tris(N-carbazoly) triphenylamine bis(vinylbenzylether) or polystyrene-N,N′-diphenyl-N,N′-bis(4-n-butylphenyl)-(1,1′-biphenyl)-4,4′-diamineperfluorocyclobutane.

19. A light-emitting device having a cathode, an anode, and a multilayered emitting polymer active layer between the electrodes, said emitting polymer layer comprising:
a single phase combination of light-emitting polymer layer and an ionic liquid;
a titanium oxide as a hole transport layer between a light emitting layer and the anode; and
4,4′,4″-tris(N-carbazoly) triphenylamine bis(vinylbenzylether) as an electron transport layer between the cathode and the light emitting layer.

20. A light-emitting device comprising a pair of electrodes, and an emitting polymer active layer between the pair of electrodes, said emitting polymer layer comprising a single phase combination of a light-emitting polymer, and an ionic liquid; and an electron transport layer between the cathode and the light emitting layer, said device formed by the process of:
i) depositing onto the anode of a layer of a solution comprising the host light-emitting polymer and the ionic liquid containing a concentration of mobile ions,
ii) spin-coating on the light-emitting polymer layer of a precursor solution of TiOx followed by 50-150° C. baking; and
iii) evaporating aluminum through a mask to form a cathode.

21. A light-emitting device having a cathode, an anode, and a multilayered emitting polymer active layer between the electrodes, said emitting polymer layer comprising:
a single phase combination of light-emitting polymer and an ionic liquid;
a titanium oxide as a hole transport layer between a light emitting layer and the anode; and
4,4′,4″-tris(N-carbazoly) triphenylamine bis(vinylbenzylether) as an electron transport layer between the cathode and the light emitting layer, said device formed by the process of:
i) coating a p-doped layer with a layer of a crosslinkable material,
ii) cross-linking said material,
iii) depositing onto the layer of crosslinkable material, a layer of a solution comprising the host light-emitting polymer and the ionic liquid containing a concentration of mobile ions,
iv) spin-coating on the light-emitting polymer layer of a precursor solution of TiOx followed by 50-150° C. baking, and
v) evaporating aluminum through a mask to form a cathode.
